(19) United States
(12) Patent Application Publication
(10) Pub. No.: US 2010/0159393 A1
(43) Pub. Date: Jun. 24, 2010

(54) METHOD OF DEVELOPING LITHOGRAPHIC PRINTING PLATE PRECURSORS

(76) Inventors: Ulrich Fiebag, Nienstadt (DE); Gerhard Hauck, Badenhausen (DE); Hans-Joachim Timpe, Osterode/Harz (DE); Friederike Von Gyldenfeldt, Osterode (DE)

Correspondence Address: EASTMAN KODAK COMPANY;PATENT LEGAL STAFF, 343 STATE STREET, ROCHESTER, NY, 14650-2201, US

(21) Appl. No.: 12/063,123

(22) PCT Filed: Aug. 18, 2006
(86) PCT No.: PCT/IB06/01039

§ 371 Date: Feb. 7, 2008

(30) Foreign Application Priority Data
Aug. 20, 2005 (GB) 0517100.4

(51) Int. Cl. G03F 7/20

(52) U.S. Cl. 430/302

(57) ABSTRACT

The invention relates to a method for making a lithographic printing plate which comprises imagewise exposing a lithographic printing plate precursor comprising one or more layers at least one of which is associated with one or more unsubstituted or substituted triarylmethane dyes and at least one of which layers is radiation-sensitive, and developing the imagewise exposed printing plate precursor with an aqueous alkaline developing composition, wherein the composition comprises at least one amphoteric surfactant of formula (I):—wherein R₁ is an unsubstituted alkyl group; each R₂ and each R₃ are independently selected from H, hydroxy and an unsubstituted or substituted alkyl group; R₄ and R₅ are independently selected from an unsubstituted alkyl group or one Of R₄ and R₅ may be the group —(CH₂)ₘ—Y—R₁; X⁻ is selected from COO⁻, SO₃⁻, OSO₃⁻, PO₃H⁻, PO₃Z⁻, OPO₃H⁻ and OPO₃Z⁻, wherein Z is a monovalent cation; Y is selected from CONH, NHCO, COO, OCO, NHCONH and O; l is 0 or 1; m is an integer from 1 to 10; and n is an integer from 1 to 5, The use of the composition for the development of radiation-sensitive positive- or negative-printing plate precursors depresses sludge formation associated with the presence of the triarylmethane dyes, thereby increasing developing capacity, and also prevents coloration of components in the developing section of the processor caused by the presence of such dyes.

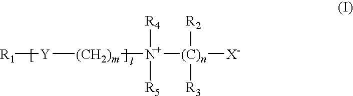

### FIELD OF THE INVENTION

The invention relates in general to lithography and in particular to a method for developing imagewise exposed positive- or negative-working lithographic printing plate precursors, including thermal printing plate precursors, with an aqueous alkaline developing composition containing an amphoteric surfactant, and in particular for the development of such printing plate precursors containing triarylmethane dyes.

### BACKGROUND OF THE INVENTION

The art of lithographic printing is based upon the immiscibility of oil and water, wherein the oily material or ink is preferentially retained by the image areas and the water or fountain solution is preferentially retained by the non-image areas of the printing plate. When a suitably prepared surface is moistened with water and ink is applied, the background or non-image areas retain the water and repel the ink while the image areas accept the ink and repel the water. The ink on the image areas is then transferred to the surface of a material upon which the image is to be reproduced, such as paper, cloth or plastics. Commonly, the ink is transferred to an intermediate material called the blanket, which in turn transfers the ink to the surface of the material upon which the image is to be reproduced.

Lithographic printing plate precursors can be either positive-working or negative-working and comprise one or more layers on a suitable substrate, such as a metal or polymeric support, at least one of these layers being radiation-sensitive. The radiation-sensitive layer generally includes one or more radiation-sensitive components that may be dispersed in a suitable binder or the radiation-sensitive component can be the binder material itself. The radiation-sensitive component may be a photosensitive component, such as an o-diazoquinone or naphthoquinonediazide (NQD) compound.

Certain useful printing plate precursors can be used either as positive-working or negative-working. The printing plate precursor is ‘positive-working’ if, after exposure to radiation, the exposed regions of the coating become more soluble in the developer than the non-exposed regions and are removed in the developing process revealing the underlying hydrophilic surface of the support. Conversely the plate precursor is ‘negative-working’ if exposed regions of the plate precursor become insoluble in the developer and the unexposed regions are removed by the developing process.

It is known in the art to include triarylmethane dyes in printing plate precursors. Such printing plate precursors may, for example, be conventional ultraviolet (UV)-sensitive positive- or negative-working plate precursors or, for example, infrared (IR)-sensitive positive- or negative-working computer-to-plate (Ctp) printing plate precursors. After processing, these dyes stay in the developing solution and may form complexes with other dissolved coating components in the developer, so that precipitation and sludge formation can occur in the developing processor. Portions of this precipitation or sludge can be transferred to the processed printing plate (re-deposition). Such re-deposits are ink-accepting and will therefore lead to incorrect printing results. Additionally a further disadvantage is the deep colour of the loaded developer which leads to a dyeing of parts of the processor such as rollers and filter cartridges, which results in a very time-consuming cleaning procedure.

Various aqueous solutions are known for use as developers for both positive-working and negative-working printing plate precursors. However many such developers are either overly active and attack or remove the unexposed image on the positive-working plate precursors or have relatively low activity, resulting in slow or incomplete development within the time suitable for practical commercial use. Further, such developers can attack an aluminium oxide layer and aluminium on the back of the printing plate precursor to such an extent that the developer activity decreases considerably and that filters in the processor can become blocked by these inorganic reaction products, resulting in time-consuming cleaning of the processor and the need for frequent changing of (expensive) filters. The decrease in the developer activity due to its reaction with the carbon dioxide in air is significant as well. Another important feature of the developer performance is its capacity, i.e. the number of printing plate precursors that can be developed before a developer change is necessary.

Developer solutions containing a silicate for the development of lithographic printing plates are well documented in the art. For example, U.S. Pat. Nos. 4,259,434 and 4,452,880 describe the use of a solution of a silicate to develop positive-working printing plate precursors.

It is further known that one or more surfactants may be included in a developer composition. GB-A-2,276,729 describes the use of an alkali metal silicate and an adduct of ethylene oxide and a sugar alcohol, together with a surfactant selected from a large number of non-ionic, cationic or amphoteric surfactants, including a carboxy- or sulfo-betaine. There is no working example or specific disclosure of the use of such a betaine in the development of a printing plate precursor containing a triarylmethane dye. EP A-0 732 628 describes the use of a developer solution comprising an alkali metal silicate and/or metasilicate and a non-ionic surfactant with at least one anionic or amphoteric surfactant for the development of o-quinonediazide printing plate precursors to reduce deposits in the processor. There is no disclosure of the effect of the specific action of certain amphoteric surfactants on triarylmethane dyes.

U.S. Pat. Nos. 3,891,438; 3,891,439 and 4,147,545 describe the use of several types of amphoteric surfactants in NQD printing plate precursors and plate precursors based on negative diazo resins. DE 3007401 discloses a method for the development of NQD plate precursors with developers containing an anionic or an amphoteric surfactant and specifically a combination of an amphoteric N-alkyl-N,N-di-hydroxyethylbetaine and a silicone-derived surfactant. The specification is silent on developer capacity and any decolorization function of such developers.

U.S. Pat. No. 4,576,743 claims printing plate cleaner compositions which contain a cationic surfactant and/or an amphoteric surfactant. There is no disclosure regarding the influence of these surfactants on printing plate precursor developer compositions.

EP A-0 992 854 discloses alkaline developer solutions for printing plate precursors of the photo-polymer type which contain an amphoteric surfactant, preferably an amino acid or alkylamidoalkylbetaine, in combination with an anionic surfactant, a complexing agent, an aminoalcohol and an amine. Although triarylmethane dyes are mentioned as one of a large number of possible dye types, there is no working example or specific disclosure of the use of such an amphoteric surfactant in a developer for a printing plate precursor having such a dye associated therewith.

EP-A-1 462 251 describes a method of developing an IR-exposed positive-working plate precursor including a novolac resin with an alkaline developing solution comprising at least one surfactant consisting of an anionic or amphoteric surfactant, such as a carboxybetaine. As an essential feature a xylenol is incorporated as a monomer component in the novolac resin to prevent deterioration in the sensitivity of the light-sensitive layer. There is no teaching of the problems associated with the use of triarylmethane dyes, nor of decolorization of the developer.

### PROBLEM TO BE SOLVED

Particular problems exist with lithographic printing precursors thereof containing triarylmethane dyes. The development of printing plate precursors which incorporate such dyes with commercially available developers has lead to both sludge generation at certain level of plate throughput and a deep coloration of the components of the developing section of the processors. Such sludge formation leads to both an unwanted re-deposition of precipitated particles onto developed printing plates and a blocking of filters in the developing section. The sludge formation decreases the performance of the developer significantly because only low throughputs (low capacity) can be reached and time-consuming procedures for cleaning of the developing processor are necessary.

### ADVANTAGEOUS EFFECT OF THE INVENTION

It has been found that the aqueous alkaline developing compositions for use in the invention can depress sludge generation resulting from the presence of the triarylmethane dyes in the printing plate precursors, so that the loading degree with printing plate precursors can be increased, e.g. developing capacity of the developer is increased. Furthermore, the coloration of components of the developing section of the processor, which requires an additional cleaning step from time to time, can be reduced or prevented.

### SUMMARY OF THE INVENTION

According to the present invention there is provided a method for making a lithographic printing plate which comprises imagewise exposing a lithographic printing plate precursor comprising one or more layers, at least one of which is associated with one or more unsubstituted or substituted triarylmethane dyes and at least one of which layers is radiation-sensitive, and developing the imagewise exposed printing plate precursor with an aqueous alkaline developing composition, wherein the composition comprises at least one amphoteric surfactant of formula (I):—

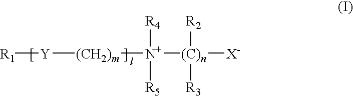

wherein

R₁ is an unsubstituted alkyl group;

each R₂ and each R₃ are independently selected from H, hydroxy and an unsubstituted or substituted alkyl group;

R₄ and R₅ are independently selected from an unsubstituted alkyl group or one of R₄ and R₅ may be the group —(CH₂)ₘ—Y—R₁;

X⁻ is selected from COO⁻, SO₃⁻, OSO₃⁻, PO₃H⁻, PO₃Z⁻, OPO₃H⁻ and OPO₃Z⁻, wherein Z is a monovalent cation;

Y is selected from CONH, NHCO, COO, OCO, NHCONH and O;

l is 0 or 1;

m is an integer from 1 to 10; and

n is an integer from 1 to 5.

In another aspect of the invention there is provided the use of an aqueous alkaline developer composition as above-defined for the reduction or removal of coloration formed during development of an imagewise exposed lithographic printing plate precursor, the coloration being caused by the presence of one or more unsubstituted or substituted triarylmethane dyes associated with one or more layers of the printing plate precursor, at least one of the layers being radiation-sensitive.

In a further aspect of the invention there is provided the use of an aqueous alkaline developer composition as above-defined for the reduction or prevention of sludge formation formed during development of an imagewise exposed lithographic printing plate precursor, the sludge being caused by the presence of one or more unsubstituted or substituted triarylmethane dyes associated with one or more layers of the printing plate precursor, at least one of the layers being radiation-sensitive.

### DETAILED DESCRIPTION OF THE INVENTION

One or more triarylmethane dyes are used in the lithographic printing plates of the invention, which dyes may be acidic or basic, are usually reds, violets, blues or greens and are characterized by high tinctorial power and brilliant hue. They include a chromophore which may appear as the grouping R¹R²C═Ar═N⁺RR′ or R¹R²C═Ar═O, wherein R¹ and R² are independently an unsubstituted or substituted aryl group, Ar is an unsubstituted or substituted aromatic nucleus and R and R′ are independently hydrogen or an unsubstituted or substituted alkyl group, R¹ and R² being attached to the methane carbon atom to complete the chromogen. The dyes are formed by the introduction of two or three auxochromes, usually in the p-position of the aromatic nucleus with respect to the methane carbon atom.

The dyes may comprise naphthyl rings but preferably phenyl rings, and in particular are derivatives of triphenylmethane and diphenylnaphthylmethane. One or more rings may be substituted with one or more substituents selected, for example, from cyan or halogen groups, or from unsubstituted or substituted alkyl, amino, alkylamino, dialkylamino, arylamino, diarylamino, alkoxy or alkylmercapto groups. The amount of dye or dyes generally present in a lithographic printing plate precursor will be about 0.01 to 20%, preferably about 0.1 to about 10%, more preferably about 0.2 to about 8%, based on the total amount of solid content of all the layers.

Typical examples of triarylmethane dyes which are all commercially available, are as follows:—

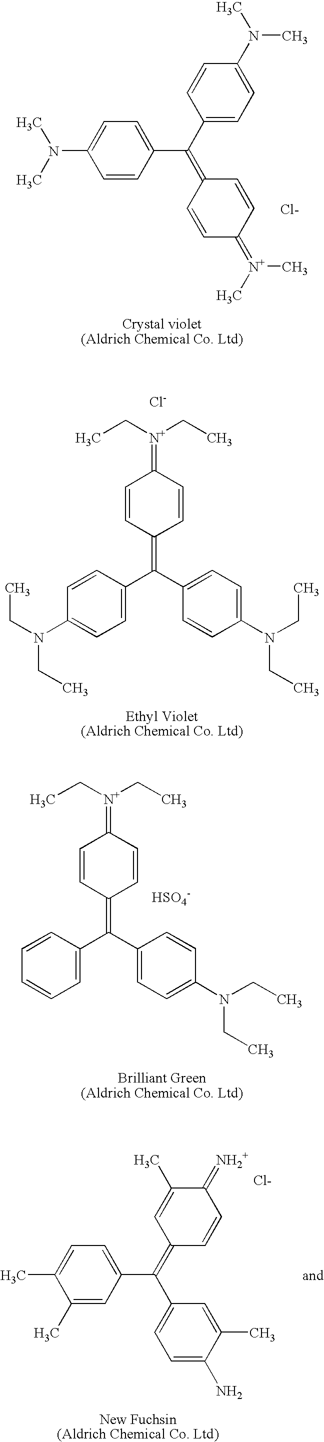

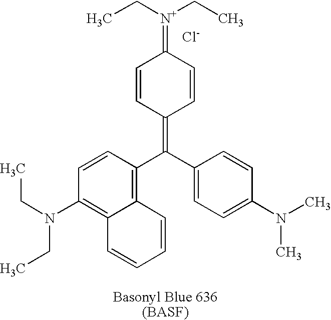

In the surfactant of formula (I), R₁ is preferably selected from an unsubstituted C₁-C₂₅ alkyl group, more preferably a C₅-C₂₀ alkyl group and most preferably a C₈-C₁₈ alkyl group. Preferably each R₂ and each R₃ is independently selected from H and a C₁-C₂₀ alkyl group, optionally substituted, for example, with one or more halogen, preferably chloro, hydroxy, C₁-C₅ alkoxy, C₁-C₅ N-alkylamido, C₁-C₅ N,N-dialkylamido or C₁-C₄-alkyl-COO— groups. More preferably each R₂ and R₃ is a C₁-C₃ alkyl group, especially unsubstituted, but most preferably each R₂ and each R₃ is a hydrogen atom. Preferably R₄ and R₅ are independently selected from an unsubstituted C₁-C₁₀ alkyl group, more preferably independently a methyl group or an ethyl group.

X⁻ is selected from COO⁻, SO₃⁻, OSO₃⁻, PO₃H⁻, PO₃Z⁻, OPO₃H⁻ and OPO₃Z⁻, preferably COO⁻, SO₃⁻ or OSO₃⁻, wherein Z is a monovalent cation, such as a cation of an alkali metal or ammonium. Y is selected from CONH, NHCO, COO, OCO, NHCONH and O, but is preferably a CONH group. l is 0 or 1 but preferably 0. m is an integer from 1 to 10, preferably 2 to 6, and n is an integer from 1 to 5, preferably 1 to 3.

In a preferred aspect of the invention the surfactant has the formula (II)

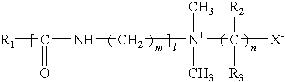

wherein

R₁, R₂, R₃, X, l, m and n are as defined for formula (I).

The composition may comprise a mixture of surfactants within the scope of formula (I). In particular a mixture of surfactants differing, for example, in the R₁ group may be used with advantage.

In one aspect of the invention, when the printing plate precursor is a heat-sensitive, positive-working lithographic printing plate precursor wherein in the surfactant of formula (I) R₁ is C₁₂H₂₅, l is 0, n is 1, R₂ and R₃ are each H, R₄ and R₅ are each CH₃ and X⁻ is COO—, a heat-sensitive layer does not contain a novolac resin which includes a xylenol as a monomer component.

In another aspect of the invention, when the printing plate precursor is a heat-sensitive, positive-working lithographic printing plate precursor wherein in the surfactant of formula (I) l is 0, R₂ and R₃ are each H, R₄ and R₅ are each CH₃ and X⁻ is COO⁻ or SO₃⁻, a heat-sensitive layer does not contain a novolac resin which includes a xylenol as a monomer component.

In a further aspect of the invention wherein in the surfactant of formula (I) l is 0, a heat-sensitive layer does not contain a novolac resin which includes a xylenol as a monomer component.

In yet another aspect of the invention, a heat-sensitive layer of the lithographic printing plate does not contain a novolac resin which includes a xylenol as a monomer component.

As used herein and throughout the specification unless where specifically stated otherwise, the term “alkyl” refers to a saturated or unsaturated, straight or branched chain alkyl group including alkenyl and aralkyl, and includes cyclic groups, including cycloalkenyl, having 3-8 carbon atoms and the term “aryl” includes fused aryl.

Examples of amphoteric surfactants which are obtainable as mixtures of surfactants within the scope of formula (I) include, for example, the following:—

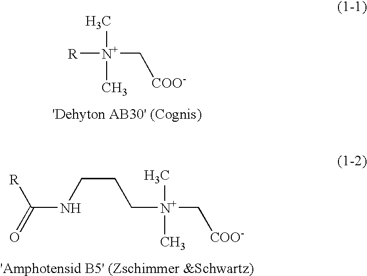

wherein in each structure R is a mixture of C₈ to C₁₈ alkyl groups, and

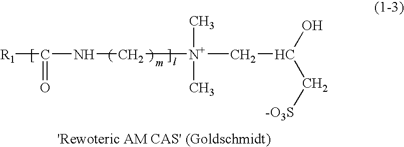

wherein R₁ is a mixture of C₆ to C₁₈ alkyl groups, m is 3 and l is 1.

Individual amphoteric surfactants within the scope of formula (I) include, for example, the following:—

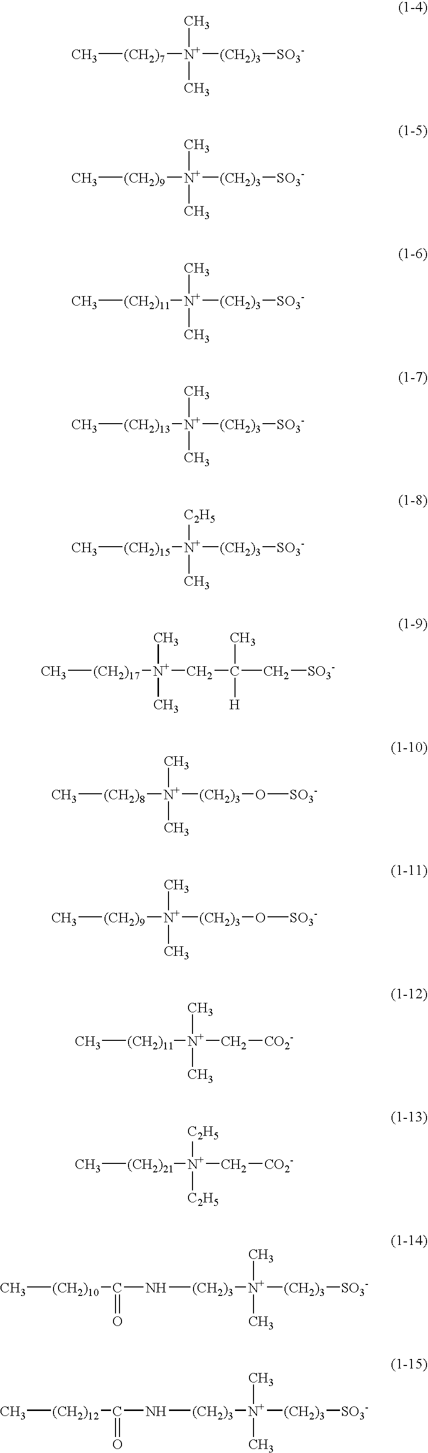

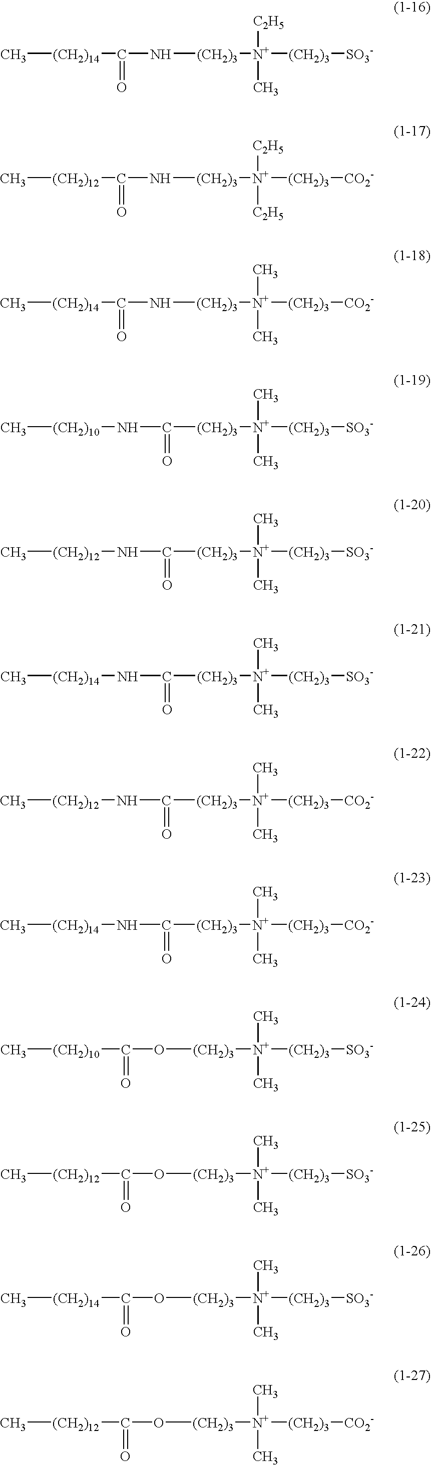

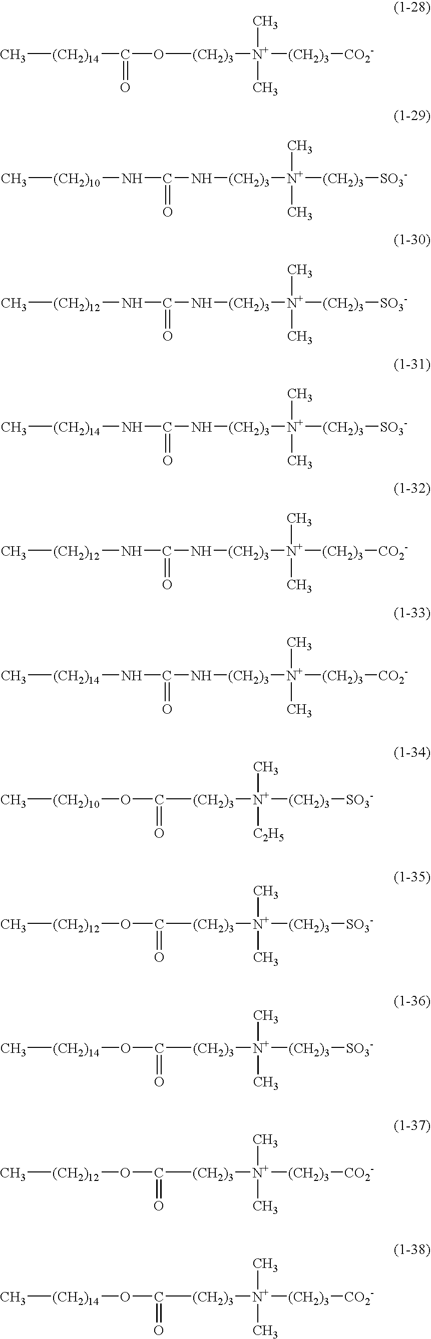

As used herein, the term ‘printing plate precursor’ refers to the material before exposure and/or development, whereas the term ‘printing plate’ is used for the material after exposure and development, i.e. a plate that is ready to print.

As used herein, the term ‘sludging’ or ‘sludge’ refers to the coloured, primarily organic deposits associated with one or more triarylmethane dyes in a printing plate precursor and not, for example, to essentially inorganic deposits caused, for example, by developer attack on an aluminium substrate of the plate precursor.

As used herein, reference to decolorization or reduction or removal of coloration pertains to the colour caused by the presence of the triarylmethane dye(s) and not to any colour of the developer solution associated, for example, with the presence of the binder.

The compositions are used for the development of alkaline developable lithographic printing plate precursors, including thermal printing plate precursors, and can be used for the simultaneous development of different kinds of plate precursors. The use of the composition for positive-working, thermal printing plate precursors, is preferred, although not limited thereto.

The positive-working or negative-working printing plate precursor may be any of those used in the art and will typically include a polymeric or a metal substrate, preferably an aluminum, aluminum alloy or treated aluminium substrate. Such substrates are well known in the art, e.g. as described in U.S. Pat. Nos. 4,259,434, 5,122,243 and 5,368,974.

When an aluminium substrate is used, it is preferred that it is first roughened by brushing in a dry state, brushing with an abrasive suspension or electrochemically, e.g. in a hydrochloric acid electrolyte. The roughened plates, which are optionally anodically oxidized in sulfuric or phosphoric acid, may then be subjected to a hydrophilizing after-treatment, preferably in an aqueous solution of polyvinylphosphonic acid or phosphate/fluoride. The details of the above-mentioned substrate pre-treatment are well-known to the person skilled in the art.

At least one radiation-sensitive layer that includes a radiation-sensitive component is provided on the substrate, either directly or over one or more other layers. The radiation-sensitive layer may be a photosensitive layer and include, for example, an o-diazoquinone, including a NQD compound, as described in U.S. Pat. No. 4,927,741 and GB 2,082,339. Especially useful are negative- or positive-working plate precursors that also contain an IR-absorbing (light-to-heat-converting) compound, rendering the radiation-sensitive layer IR-sensitive, i.e. so-called ‘thermal’ printing plate precursors.

Although the radiation-sensitive components may be used alone, more typically they are dispersed in a suitable binder material that is soluble in the alkaline developing composition. Such binder materials will normally be a polymeric resin and may be, but not limited to, novolac-type phenolic resins and others readily apparent to one skilled in the art.

Novolac resins are commercially available and are well known to those skilled in the art. They are typically prepared by the condensation reaction of a phenolic compound, such as phenol, m-cresol, o-cresol, p-cresol, etc. with an aldehyde, such as formaldehyde, paraformaldehyde, acetaldehyde, etc., or a ketone, such as acetone, in the presence of an acid catalyst. The weight average molecular weight is generally about 1,000 to 15,000 g/mol. Typical novolac resins include, for example, phenol-formaldehyde resins, cresol-formaldehyde resins, phenol-cresol-formaldehyde resins, p-t-butylphenol-formaldehyde resins and pyrogallol-acetone resins. Particularly useful novolac resins are prepared by reacting m-cresol, mixtures of m-cresol and p-cresol, or phenol with formaldehyde using conventional conditions.

Other useful binders are acetal polymers, and in particular polyvinylacetal polymers, which are the reaction products of poly(vinyl alcohol) with aldehydes, wherein that part of the aldehyde incorporated into the polymer comprises alkaline-soluble groups, such as, for example, phenolic groups (e.g. derived from hydroxybenzaldehyde), carboxy groups derived from carboxy benzaldehyde, or acidic groups such as, for example, sulfonic or phosphonic acid, derived from the corresponding aldehydes. Acetals that may be suitable for use as binders in the present invention include those described in WO 01/09682, WO 2004/081662 and WO 2004/020484, the disclosures of which are incorporated herein by reference.

The binders may be based on homo and/or copolymers of, for example, hydroxystyrene, acrylic acid, methacrylic acid or other derivatives of acrylic acid, maleiimide, maleic anhydrides, hydroxyl or carboxy functionalised celluloses, urethane- or acetal-groups containing polymers comprising acid groups and sulfonamide-groups containing polymers. For example the homopolymers may be polyacrylic acid or polymethacrylic acid and the copolymers which will comprise different monomers may be, for example, a copolymer of acrylic acid and methacrylic acid. However any printing plate precursor that includes a triarylmethane dye, including those not including a binder based on novolac resins or acetal polymers that can be developed with the compositions herein described, may be used.

Other additives that can be included with advantage in the radiation-sensitive material include, for example, dyes other than triarylmethane dyes, pigments, plasticizers, Brönsted acid precursors, radical generators, IR-absorbing compounds, sensitizers, stabilizers and components, such as leucodyes, that produce print-out images.

In accordance with the invention there may be more than one radiation-sensitive layer in the radiation-sensitive material and also there may be present other layers that are not radiation-sensitive. For example, an undercoating layer may be present between the substrate and a radiation-sensitive layer. Moreover on top of the radiation-sensitive layer(s), for example, an oxygen impermeable layer may be applied as it is known in the art, e.g. a layer of polyvinyl alcohol, polyvinyl alcohol/polyvinyl acetate copolymers, polyvinyl pyrrolidone, polyvinyl pyrrolidone/polyvinyl acetate copolymers, polyvinyl methylether, polyacrylic acid, polyvinyl imidazole and gelatin, used either alone or in combination. This overcoat not only serves as an oxygen barrier but also protects the plate against ablation during exposure to the radiation.

Upon imagewise exposure of a positive-working printing plate precursor using a suitable light source, the exposed regions of the radiation-sensitive coating become more soluble in the alkaline developer and can be washed away leaving the surface of the support underneath. The change in solubility may be based on a chemical change upon exposure, for example conversion of a NQD compound in a photosensitive layer into indene carboxylic acid. Since the surface of the support is hydrophilic, the uncovered non-image areas attract water and repel the oily ink. The image area remaining after development is oleophilic, thereby repelling water and attracting the printing ink.

However the change in solubility may be based on a physical change, namely “reversible insolubilization” or “dissolution inhibition”, based on complex formation. Thus some positive-working thermal printing plate precursors are based on a complex of “active polymer”, such as for example a phenolic resin, and a “reversible insolubilizer” compound, which forms a thermally-frangible complex with the active polymer so the plate precursor is heat-sensitive. By the application of heat, differentiation between image and non-image areas can be achieved. This complex is less soluble in the developer solution than the non-complexed active polymer. However when this complex is imagewise heated the complex breaks down, allowing the non-complexed active polymer to be dissolved in the developing solution. It is also possible to have an IR light-to-heat-converting compound (i.e. an IR-absorber) in the coating, so that upon imagewise exposure the complex can be destroyed.

It is believed that the complex is reversibly formed and can be broken by the application of heat to the complex to restore aqueous developer solubility to the composition. The polymeric substances which are suitable for this kind of complex formation are believed to comprise electron-rich functional groups when non-complexed and that suitable compounds which reduce the aqueous developer solubility of the polymeric substance are electron-poor. It is not thought that decomposition of the components within the composition is required.

Examples of such “reversible insolubilizing” compounds which are able to form thermally frangible complexes are quinolinium compounds, benzo-thiazolium compounds, pyridinium compounds, imidazoline compounds and several types of cationic dyes, including triarylmethane dyes as described in U.S. Patent Publication No. 2002/045124.

Upon imagewise exposure of a negative-working printing plate precursor using a suitable light source, the exposed regions of the radiation-sensitive coating become insoluble in the alkaline developer and it is the unexposed regions that are washed away with the alkaline developing composition of this invention to reveal the hydrophilic substrate underneath. The printing plate precursor may be heated to harden the exposed regions.

This decrease in solubility is generally obtained by cross-linking of the coating, which can be obtained by the use of radicals, acids or bases. Molecules that can be easily crosslinked are C═C bond-containing molecules (monomers, oligomers, polymers) or resoles, in the case of acid cross-linking. The radical/acid or base generator has to be activated in the spectral region used for the exposure.

Several IR-sensitive compositions for preparing negative-working thermal printing plate precursors may contain, in addition to the IR-absorbing compound, a polymeric binder, a free radical polymerizable system consisting of at least one member selected from unsaturated free radical polymerizable monomers, oligomers which are free radical polymerizable and polymers containing C═C bonds in the backbone and/or in the side chain groups and an initiator system that is able to generate radicals. Such materials are well known in the art, as described, for example, in U.S. Pat. No. 5,372,907. As unsaturated free radical polymerizable monomers or oligomers, use can be made of, for example, acrylic or methacrylic acid derivatives with one or more unsaturated groups, preferably esters of acrylic or methacrylic acid in the form of monomers, oligomers or pre-polymers, as described in U.S. Pat. No. 6,309,792.

Useful IR-absorbing compounds for positive- or negative-working printing plate precursors typically have a maximum absorption wavelength in some part of the electromagnetic spectrum greater than about 750 nm, more particularly in the range from about 800 to about 1100 nm. Typical examples of such IR-absorbing compounds are triarylamine dyes, thiazolium dyes, indolium dyes, oxazolium dyes, cyanine dyes, polyaniline dyes, polypyrrole dyes, polythiophene dyes and phthalocyanine pigments.

A laser or other source of IR radiation can be used to increase, in the case of positive-working printing plate precursors, or decrease, in the case of negative-working printing plate precursors, the solubility in exposed regions of the plate precursor. If such an IR-radiation source is computer-controlled, it is possible to transfer digitized information, which is typically stored on a computer disk or a computer tape, directly to the printing plate precursor. This type of exposure is called “computer-to-plate” (Ctp) exposure and the corresponding printing plate precursors are called Ctp printing plate precursors.

The bits of information in a digitized record correspond to the image elements or pixels of the image. This pixel record is used to control an exposure device, such as a semiconductor laser or laser diode, which emits a beam in the range 800-1100 nm. The position of the exposure beam, in turn, may be controlled by a rotating drum or a lead screw, wherein the exposure beam is turned on and off in correspondence with the pixels to be printed, being digitally controlled by the computer. Alternatively the position of the exposure beam may be controlled by a turning mirror (flying spot apparatus) in which case the beam is permanently on, but the mirror brings the beam onto the printing plate precursor or brings it away therefrom.

The exposure beam is focused onto the pre-sensitized, unexposed, lithographic printing plate precursor, the imagewise exposure of the plate precursors being effected via the stored digitalized information in the computer. The exposed plate precursor is submitted to any required processing steps, such as removal of exposed material, in the case of positive-working printing plate precursors, or the removal of unexposed material, in the case of negative-working printing plate precursors, washing, gumming, etc., to produce a lithographic printing plate ready for the printing press.

The Ctp method of plate making is contrasted with the conventional method, which involves the use of an exposed and processed film of the image to be printed. In that method the image on the film is then transferred with UV radiation onto the sensitized, unexposed printing plate precursor, followed by the required plate processing procedures. The Ctp method of directly imaging a lithographic plate does not require the use of any film and thus contributes to savings in film costs and processing. A variety of materials are known for such plates, as described, for example, in U.S. Pat. Nos. 5,340,699, 5,466,557 and 5,491,046.

In the developing composition, the surfactant of formula (I) or a mixture thereof may be used in a (total) amount of from about 0.01 to about 20 wt %, preferably from about 0.1 to about 10 wt % and most preferably from about 0.2 to about 5%, based on the total composition weight.

Furthermore, the aqueous composition will essentially contain alkaline components. Alkali metal silicates, e.g. compounds containing SiO₂ and M₂O with M being an alkali metal, for example lithium, sodium or potassium, are preferred as such components. Types of alkali metal silicates that can be used are metasilicates, having a molar ratio of SiO₂ to M₂O of and waterglasses, having a molar ratio of SiO₂ to M₂O of ≧2, although it is also possible to use alkali metal silicates having a molar ratio of SiO₂ to M₂O of from 1 to 2. It is preferred for this invention however, but not limited thereto, to use a combination of metasilicates and waterglasses. A solution of alkali metal silicate is typically sold with the concentration indicated by “° Baumé”, degrees Baumé being a measure of the specific gravity.

The amount of metasilicate is not limited but it is preferred that the aqueous alkaline composition contains from about 1 to about 50 wt %, especially from about 5 to about 25 wt % and most preferably from about 8 to about 15 wt % alkali metasilicate. The waterglass, if present, will generally be present in a smaller amount, typically about 5 wt %, but the amount will be dependent upon the other alkaline compositions in the developer composition.

The composition has an alkaline pH, typically at least about 11, preferably at least about 12 and more preferably about 12 to about 14. Alkalinity can be provided additionally to the alkali metal silicates by using a suitable concentration of any suitable chemical base such as, for example, an alkali metal hydroxide, such as sodium hydroxide, lithium hydroxide or potassium hydroxide, or phosphoric acid used in combination with an alkali hydroxide to form a buffer of alkali metal phosphate.

Optionally, in addition to the surfactant of formula (I) or mixtures thereof, one or more other surfactants (anionic, nonionic and/or amphoteric), chelating agents, solvents, polyglycol derivatives, phosphonic acid derivatives, organic or inorganic salts, biocides (antimicrobial or antifungal agent) or antifoaming agents, such as certain silicones, may also be included

Preferably the surfactant of formula (I) is dissolved in the developing composition with the other components at the outset, but it may also be added later on if the developing composition is already loaded, and the benefits of the invention can still be achieved.

Development of a positive- or negative-working printing plate precursor is generally conducted at a temperature of from about 18 to about 28° C. for a period of from about 5 to about 60 seconds.

The aqueous alkaline composition of the invention can be used either as a developer or a replenisher or as both a developer and a replenisher. In the so-called “top-up development mode”, the developer is used to regenerate the developing solution after a predetermined amount of precursor plates have been developed, to maintain the volume and the activity of the developer. Usually about 80 ml to about 200 ml (typically about 100 to about 130 ml) of developer/m² of exposed printing plate precursors that are processed are required.

In contrast thereto the “replenishment mode” uses a “replenisher” solution which contains the same components as the developer, but in a different ratio. The replenisher has a conductivity higher than that of its corresponding developer. This can, for instance, be obtained by having a higher concentration of alkali metal hydroxide in the replenisher, whilst keeping the concentrations of the other components the same in both the developer and the replenisher.

After the developer has been used to develop a predetermined number of printing plate precursors, the replenisher is added to the processor that contains the developer. Usually about 30 ml to about 100 ml (typically about 40 to about 60 ml) of replenisher/m² of exposed printing plate precursors processed are necessary to keep constant the volume of developer and hence the activity of the developer in the processor. For example, the conductivity of the developer is from about 50 to about 100 mS/cm, typically from about 80 to about 95 mS/cm, at 20° C. The conductivity of the corresponding replenisher is usually from about 60 to about 150 mS/cm, typically from about 110 to about 140 mS/cm, at 20° C., but always higher than that of the developer to be regenerated.

Advantages associated with the use of the method of the invention include: high through-put of the plate precursors, clean and constant development, the possibility of replenishment by either conductivity control or conventional replenishment, no sludge generation in the processor, little or no coloration of components in the developing section of the processor, easy cleaning of the processor and minimal waste as a result of the high developing capacity of the developer.

The patents and publications referred to herein are incorporated by reference in their entirety.

The invention will be described with reference to the following examples, which in no way are to be construed as limiting the scope of the invention.

### EXAMPLES

### Synthesis of Compounds of Formula (I)

I-1, I-2 and I-3 are available commercially, as indicated in the Examples below. Synthetic methods for some individual surfactants are outlined below, using methods well known in the art.

The single or final step in the synthesis of compounds I-4 to I-38 is alkylation with, for example, either a 1,3-propane sultone or a corresponding compound with the anion-forming group having a terminal chloro or bromo group. For example, I-4 to I-9, I-10 and I-11, I-12 and I-13 can be prepared by reaction thereof with the appropriate N,N,N-tri-alkylamine starting material (e.g. I-4 can be prepared from the reaction of N,N,N-dimethyl octylamine with 1,3-propane sultone, I-10 by the reaction of N,N,N-dimethyl nonylamine with 3-chloropropyl sulfate and I-12 by the reaction of N,N,N-dimethyl dodecylamine with 3-chloroacetic acid).

The synthesis of I-14 to I-18 requires an initial step of reacting N,N-di-alkyl trimethylene diamine with the appropriate carboxylic acid chloride (e.g. dodecanoyl chloride) before the subsequent alkylation step as above. The initial step in the synthesis of I-29 to I-33 is the reaction of N,N-dimethyl trimethylene diamine with the appropriate alkyl isocyanate (e.g. undecyl isocyanate for I-29, followed by the alkylation step as before, and the first step in the synthesis of I-34 to I-38 is the reaction of N,N,N-(3-carboxyethyl) dimethylamine with undecanol and then the alkylation step.

Analogues and homologues of the above compounds can be prepared by methods similar to the above, as will be readily appreciated by the skilled artisan.

### Developer/Replenisher Solutions

### Example 1

### Preparation of Developer Solution Inv-1

A developer composition was prepared from the following components under stirring:

| | |
|---|---|
| Water | 91.6 kg |
| Sodium metasilicate | 12.2 kg |
| Sodium silicate (37/40° Baumé) | 2.2 kg |
| Akypo ® LF2 (Kao Chemicals) (anionic surfactant) | 1.0 kg |
| Dehyton ® AB30 (40 wt. % aqueous solution; Cognis) (1-1) | 1.3 kg |
| (lauryl dimethylaminoacetic betaine) (amphoteric surfactant) | |
| Silicon-Antifoam emulsion SE 57 (Wacker) | 0.04 kg |

### Example 2

### Preparation of Developer Solution Inv-2

A developer composition was prepared from the following components under stirring:

| | |
|---|---|
| Water | 91.6 kg |
| Sodium metasilicate | 12.2 kg |
| Sodium silicate (37/40° Baumé) | 1.1 kg |
| Crystal L40 (lithium silicate, manufactured by SPCI) | 1.1 kg |
| Rewoteric ® AM-CAS (50 wt. % aqueous solution; | 0.9 kg |
| Goldschmidt) (1-3) (3-(3-cocamidopropyl)dimethylammonium- | |
| 2-hydroxypropanesulfonate) (amphoteric surfactant) | |
| Silicon-Antifoam emulsion SE 57 (Wacker) | 0.04 kg |

### Example 3

### Preparation of Developer Solution Inv-3

A developer composition was prepared from the following components under stirring:

| | |
|---|---|
| Water | 90.4 kg |
| Sodium metasilicate | 12.2 kg |
| Sodium silicate (37/40° Baumé) | 2.2 kg |
| Synperonic 304T (ICI Chemicals) (non-ionic | 0.17 kg |
| surfactant) | |
| Amphotensid B5 (40 wt. % aqueous solution; (1-2) | 2.5 kg |
| Zschimmer & Schwarz) (amphoteric surfactant) | |
| Silfoam SRE (Wacker) | 0.04 kg |

### Example 4

### Preparation of Developer Solution Inv-4

A developer composition was prepared from the following components under stirring:

| | |
|---|---|
| Water | 70.7 kg |
| Potassium hydroxide (45 wt. % aqueous solution) | 13.5 kg |
| Phosphoric acid (85 wt. % aqueous solution) | 2.6 kg |
| Potassium silicate (42/43° Baumé) | 7.3 kg |
| Glycol | 4.4 kg |
| Dehyton ® AB30 (40 wt. % aqueous solution; Cognis) (1-1) | 1.3 kg |
| Sequion 10 NA (Polygon) | 0.3 kg |
| (1-Hydroxyethylene-1,1,-diphosphonic acid tetrasodium salt) | |
| Pluriol P600 (10 wt. % aqueous solution; BASF) | 0.02 kg |
| (polypropylene glycol) | |
| Silfoam SRE (Wacker) | 0.04 kg |

### Example 5

### Preparation of Replenisher Solution Inv-5

The replenisher composition was prepared from the following components under stirring:

| | |
|---|---|
| Water | 77.3 kg |
| Potassium hydroxide (45 wt.-% aqueous solution) | 17.9 kg |
| Phosphoric acid (85 wt. % aqueous solution) | 2.8 kg |
| Potassium silicate (42/43° Baumé) | 7.9 kg |
| Glycol | 4.7 kg |
| Dehyton ® AB30 (40 wt. % aqueous solution; Cognis) (1-1) | 1.3 kg |
| Sequion 10 NA (Polygon) | 0.3 kg |
| Pluriol P600 (10 wt. % aqueous solution; BASF) | 0.02 kg |
| (polypropylene glycol) | |
| Silfoam SRE (Wacker) | 0.04 kg |

### Example 6

### Preparation of Comparative Developer Solutions Cmp-1 to Cmp-5

Developer compositions were prepared from the following components under stirring:

| | |
|---|---|
| Water | 92.9 kg |
| Sodium metasilicate | 12.2 kg |
| Sodium silicate (37/40° Baumé) | 2.2 kg |

Antifoam emulsion as in TABLE 1
Comparative surfactant C-1 to C-5 as in TABLE 1

TABLE 1 summarizes the type and amount of comparative surfactants C-1 to C-5, the structures of which are shown thereafter, none of these having a structure falling within formula (I):—

TABLE 1

| | | Surfactant Type | Surfactant | Anti-foam |
|---|---|---|---|---|
| Composition | Surfactant | (supplier) | (amount) | (amount, supplier) |
| Cmp-1 | C-1 | anionic | Akypo ® LF2 | SE 57 |
| | | (Kao Chemicals) | (0.35 kg) | (0.04 kg, Wacker) |
| Cmp-2 | C-2 | non-ionic | Synperonic 304T | Silfoam SRE |
| | | (ICI) | (0.17 kg) | (0.04 kg, Wacker) |
| Cmp-3 | C-3 | amphoteric | Amphotensid D1 | Silfoam SRE |
| | | (Zschimmer & | (0.40 kg) | (0.04 kg, Wacker) |
| | | Schwarz) | | |
| Cmp-4 | C-4 | amphoteric | Amphotensid CT | SE 57 |
| | | (Zschimmer & | (0.20 kg) | (0.04 kg, Wacker) |
| | | Schwarz) | | |
| Cmp-5 | C-5 | amphoteric | Rewoteric AMV | Silfoam SRE |
| | | (Goldschmidt) | (0.40 kg) | (0.04 kg, Wacker) |

Comparative surfactants
C₈H₁₇(OC₂H₄)₈OCH₂COOH
Akypo LF 2
C-1
Polypropyleneoxide/polyethylenoxide
block copolymer adduct on ethylenediamine
Synperonic 304T
C-2
C₁₂H₂₅NHCH₂CH₂COOH + (HOC₂H₅)N
Amphotensid D1
C-3

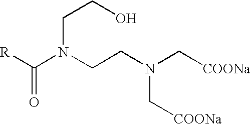

Amphotensid CT (or Dehyton MC)
wherein R is a mixture of C₁₂-C₁₈ alkyl groups
C-4

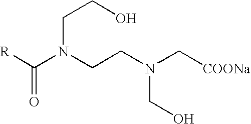

Rewoteric AMV
wherein R is a mixture of C₅-C₁₀ alkyl groups
C-5

### Example 7

### Preparation of Comparative Developer Solution Cmp-6

Developer compositions were prepared from the following components under stirring:

| | |
|---|---|
| Water | 72 kg |
| Potassium hydroxide (45 wt. % aqueous solution) | 13.5 kg |
| Phosphoric acid (85 wt. % aqueous solution) | 2.6 kg |
| Potassium silicate (42/43° Baumé) | 7.3 kg |
| Glycol | 4.4 kg |
| Sequion 10 NA (Polygon) | 0.3 kg |
| Pluriol P600 (10 wt. % aqueous solution; BASF) | 0.02 kg |
| Silfoam SRE (Wacker) | 0.04 kg |

### Example 8

### Preparation of Comparative Replenisher Solution Cmp-8

The replenisher composition was prepared from the following components under stirring:

| | |
|---|---|
| Water | 78.6 kg |
| Potassium hydroxide (45 wt. % aqueous solution) | 17.9 kg |
| Phosphoric acid (85 wt. % aqueous solution) | 2.8 kg |
| Potassium silicate (42/43° Baumé) | 7.9 kg |
| Glycol | 4.7 kg |
| Sequion 10 NA (Polygon) | 0.3 kg |
| Pluriol P600 (10 wt. % aqueous solution; BASF) | 0.02 kg |
| Silfoam SRE (Wacker) | 0.04 kg |

### Example 9

### Processing of Positive-Working Thermal Plate Precursors

The triarylmethane dye-containing, positive-working, printing plate precursors Electra Excel™ used in the following examples are available from Kodak™ Polychrome Graphics (KPG) LLC.

They were cut to a size of 515×790 mm and exposed in the IR-exposure unit Trendsetter 3244 (20 W head; Creo) using a W-power of 10 W and a rotational speed of 180 rpm. The Kodak™ Professional Colorflow Strip (available from Eastman Kodak™ Co.), which contains different elements for evaluating the quality of the copies, was used for evaluation.

Commercially available processors (Mercury MK6 or Sprinter, both from KPG LLC), equipped with an immersion-type developing bath, a section for rinsing with water and a gumming and drying section, were used to develop the exposed plate precursors. The processor was filled either with 40 l (Mercury MK6) or 20 l (Sprinter) of appropriate developer. Separately, a container for fresh developer was attached, from which 100 ml developer/m² developed plate were added to the developing bath via a pump. The following other processor parameters were kept constant in all tests: temperature of the developing bath—(23±1)° C.; dwell time in the developer—45 sec.

Exposed Electra Excel™ plate precursors were developed one after another at a rate of 150 plates per day and the following parameters were monitored: performance of developer solution, performance of filters of processor and quality of copies. To evaluate the copies obtained after development, the following criteria were examined: reproduction of the 1 and 2 pixel elements and optical density of the checker-board dots of the pixel elements (measured with the apparatus D19C/D, from Gretag/Macbeth).

After finishing the loading process, loaded developer solutions were removed and the performance of components of the developer section (plastic parts, brushes, rollers etc) were evaluated. The results for developers Inv-1, Inv-2 and Inv-3 and comparative developers Cmp-1, Cmp-2 and Cmp-7 are listed in TABLE 2, which shows the performance of these developers with thermal, positive-working printing plate precursors.

The filters of the processor were monitored to see whether filter blocking and sludge formation occurred. The figures in TABLE 2 give the amount (in m²) of processed plates/l (filled in the processor) before filter blocking and sludging occurred: the higher the figures the higher the degree of loading (through-put in m²), i.e. the higher the capacity. Thus a figure of >40 in columns 4 and 5 of TABLE 2 means that with a processor with a 40 l tank, more than 40×40 m² of plates could be processed before filter blocking or sludge formation occurred with the developer for use in the invention. It will be seen that the comparative developers had a lower through-put before filter blocking and sludge formation occurred.

For comparative developers Cmp-3 to Cmp-6 the following short test was carried out. Using the above-described method, only 2 m²/l exposed Electra Excel™ plate precursors were developed and, after this throughput, the colour of loaded developer solution was monitored. In contrast to the situation with developers Inv-1 to Inv-3 of the invention, which were all transparent, the loaded developer solutions with comparative developers were all deep blue coloured.

TABLE 2

| | | | Filter | Sludge | |
|---|---|---|---|---|---|
| | | Copy | blocking* | formation.** | Performance of |
| Developer | Processor | parameter | (m²/l) | (m²/l) | developing section |
| Inv-1 | Mercury | good | >40 | >40 | very little precipitate, |
| | MK6 | | | | transparent solution, all |
| | | | | | components clear, no blue |
| | | | | | dyed |
| Inv-2 | Sprinter | good | >40 | 40 | little precipitate, |
| | | | | | transparent solution, all |
| | | | | | components clear, very few |
| | | | | | blue coloured |
| Inv-3 | Sprinter | good | >41 | >40 | very little precipitate, |
| | | | | | transparent solution, all |
| | | | | | components clear, no blue |
| | | | | | dyed |
| Cmp-1 | Mercury | good | 27 | 20 | much precipitate, deep blue |
| | MK6 | | | | solution, all components |
| | | | | | strongly blue dyed |
| Cmp-2 | Sprinter | good | 25 | 18 | much precipitate, deep blue |
| | | | | | solution, all components |
| | | | | | strongly blue dyed |
| Cmp- | Mercury | good | 29 | 21 | precipitate, deep blue |
| 7*** | MK6 | | | | solution, all components |
| | | | | | strongly blue dyed |

*50 μm filters, calculated/1 filled developer
**calculated/1 filled developer
***Goldstar ™ developer (from KPG LLC), not containing an amphoteric surfactant of the invention.

As will be seen in TABLE 2, use of the surfactants within formula (I) resulted in good copy parameters, no filter blocking, no sludge formation and a brownish-coloured developer. Use of the comparative surfactants resulted in sludge formation, blocked filters and deeply blue coloured developer.

### Example 10

### Processing of Positive-Working Printing Plate Precursors

Easyprint® and Virage™ triarylmethane dye-containing, positive-working lithographic printing plate precursors, (obtainable from KPG LLC) were cut into 790×850 mm test plates and exposed with a metal halide lamp (MH-Burner, available from Sack) with 510 mJ/cm² (Easyprint®) and 525 mJ/cm² (Virage™) under a silver halide film half-step wedge (Fogra) with a density range of 0.15 to 1.95 increments as a positive copy.

A commercially available processor (Mercury 850; KPG LLC), equipped with an immersion type developing bath, a section for rinsing with water, a gumming section and a drying section, was used to develop the exposed plate precursors. The processor was filled with 60 l of the appropriate developer. Separately, a container for the replenisher or developer, respectively, was attached from which 100 ml/m² of exposed plate precursor of replenisher solution or the appropriate developer was added to the developing bath via a pump. The temperature of the developing bath, (23±1)° C., and dwell time in the developer, 25 sec, were kept constant in all tests.

Exposed Easyprint® or Virage™ plate precursors were developed one after another at a rate of 140 plate precursors per day, and the following parameters were monitored: performance of developer solution, performance of filters of processor and quality of copies. To evaluate the copies obtained after development, the following criteria were examined:

(1) Number of steps after gray wedge exposure that did not retain coating after development (in the following referred to as GW, which is a measure of the speed of a plate: at a given exposure energy, the lower the GW, the lower the sensitivity of the plate).

(2) Microlines in a test pattern that had not been attacked to assess resolution (in the following referred to as ML- the lower the number, the greater the resolution, indicating less image attack).

After finishing the loading process with a throughput of 20 m²/l, the loaded developer solutions were removed and the performance of components of the developer section (plastic parts, brushes, rollers, etc.) were evaluated.

The results for developers Inv-1 (replenisher same as developer in top-up mode) and Inv-4 (with replenisher of Example 5) and for comparative developers Cmp-1 (replenisher same as developer in top-up mode) and Cmp-6 (with replenisher of Example 8) with conventional positive plate precursors are listed in TABLE 3.

TABLE 3

| | | Plate | | |
|---|---|---|---|---|
| Developer | Replenisher | Precursor | Copy results | Performance of developing section |
| Inv-1 | Inv-1 | Easyprint ® | GW 3, ML 10/12 | transparent solution, all components |
| | | | | clear, no blue dyed |
| Inv-4 | Inv-5 | Easyprint ® | GW 3, ML 10/12 | transparent solution, all components |
| | | | | clear, no blue dyed |
| Inv-4 | Inv-5 | Virage ™ | GW 3/4, ML 10/12 | transparent solution, all components |
| | | | | clear, no blue dyed |
| Cmp-1 | Cmp-1 | Virage ™ | GW 3/4, ML 10/12 | deep blue solution, all components |
| | | | | strongly blue dyed |
| Cmp-6 | Cmp-8 | Easyprint ® | GW 3, ML 10/12 | deep blue solution, all components |
| | | | | strongly blue dyed |
| Cmp-6 | Cmp-8 | Virage ™ | GW 3/4, ML 10/12 | deep blue solution, all components |
| | | | | strongly blue dyed |

It will be seen in TABLE 3 that the use of the surfactants of formula (I) provided similar plate properties to the comparative surfactants. However the solutions were transparent and all the components of the developer section of the processor were clear, i.e. there was no coloration remaining associated with the triarylmethane dyes. In contrast thereto, the use of the comparative surfactants resulted in deep blue solutions with all components of the developing section of the processor being also strongly blue coloured, i.e. the coloration associated with the dyes was retained.

### Screening of Dye Bleaching

### Example 11

A composition was prepared from the following components under stirring:

| | |
|---|---|
| Water | 916 g |
| Sodium metasilicate | 122 g |
| Sodium silicate (37/40° Baumé) | 22 g |

Surfactant (see TABLE 4)

Except where otherwise indicated, about 5 mg of various triarylmethane dyes (all from Aldrich Chemical Co.) and dyes other than triarylmethane dyes, all as mentioned in TABLE 4 and identified thereafter, were dissolved in 50 ml of this solution and stored under yellow-room light conditions

The compositions for use in the invention (Inv) comprised both a triarylmethane dye and a surfactant of formula (I). The comparative compositions (Cmp) comprised either a triarylmethane dye with a surfactant not within formula (I) (as identified after TABLE 4) or a surfactant within formula (I) but with a dye other then a triarylmethane dye. After a storage for 8 h at room temperature, it was determined whether bleaching of initial colour took place.

TABLE 4

| Inv/ | | | | Type of | |
|---|---|---|---|---|---|
| Cmp | Dye | Type of dye | Added surfactant (g) | surfactant | Result |
| Inv | crystal violet | cationic triarylmethane | Dehyton ® AB30 (0.7) | amphoteric | colourless |
| Inv | ethyl violet | cationic triarylmethane | Dehyton ® AB30 (0.7) | amphoteric | colourless |
| Inv | brilliant green | cationic triarylmethane | Amphotensid B5 (0.7) | amphoteric | colourless |
| Inv | new fuchsin | cationic triarylmethane | Amphotensid B5 (0.7) | amphoteric | colourless |
| Inv | crystal violet | cationic triarylmethane | Rewoteric AM-CAS (0.7) | amphoteric | colourless |
| Cmp | ethyl violet | cationic triarylmethane | Amphotensid D1 (0.7) | amphoteric | deep blue |
| Cmp | ethyl violet | cationic triarylmethane | Akypo ® LF2 (0.7) | anionic | deep blue |
| Cmp | ethyl violet | cationic triarylmethane | Surfynol 456 (0.5) | non-ionic | deep blue |
| Cmp | ethyl violet | cationic triarylmethane | Emcol E 607 L (0.8) | cationic | deep blue |
| Cmp | ethyl violet | cationic triarylmethane | Petro AA (0.8) | anionic | deep blue |
| Cmp | rhodamine 6G | cationic xanthene | Dehyton ® AB30 (0.7) | amphoteric | red |
| Cmp | ethyl eosin* | xanthene | Amphotensid B5 (0.7) | amphoteric | red |
| Cmp | methylene blue | cationic thiazine | Dehyton ® AB30 (0.7) | amphoteric | deep blue |
| Cmp | safranine G | cationic azine | Dehyton ® AB30 (0.7) | amphoteric | red |

*only 2 mg dye, dissolved with heating
Comparative dye structures

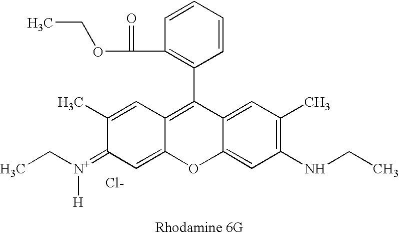

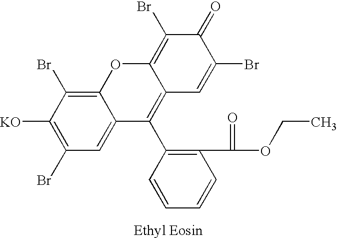

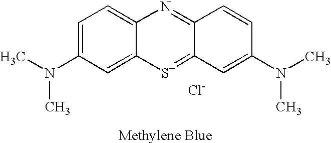

and

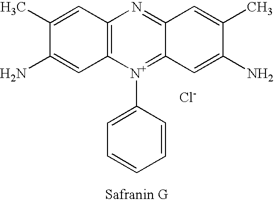

Comparative surfactant structures:

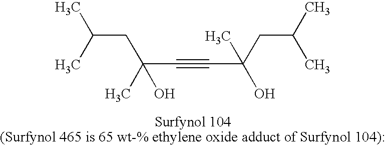

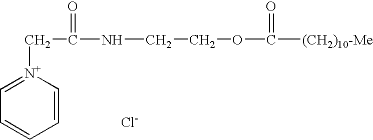

Emcol E 607
(Lauryl colamino formylmethyl pyridinium
chloride or Lapyrium chloride)
Methylnaphthalenesulfonate
Petro AA

TABLE 4 shows the “decolorization power” of compounds according to formula (I). It will be seen that decolorization only takes place if the “right” amphoteric surfactant, i.e. within formula (I), is associated with the “right” dye, namely a triarylmethane dye. The other dyes are not decolorized by these compounds, nor are the amphoteric surfactants outside formula (I) able to decolorize the triarylmethane dyes, showing the selective nature of the specific combination of triarylmethane dye and surfactant of formula (I) as claimed herein.

1. A method for making a lithographic printing plate which comprises imagewise exposing a lithographic printing plate precursor comprising one or more layers at least one of which is associated with one or more unsubstituted or substituted triarylmethane dyes and at least one of which layers is radiation-sensitive, and developing the imagewise exposed printing plate precursor with an aqueous alkaline developing composition, wherein the composition comprises at least one amphoteric surfactant of formula (I):— 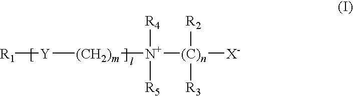
wherein
R₁ is an unsubstituted alkyl group;
each R₂ and each R₃ are independently selected from H, hydroxy and an unsubstituted or substituted alkyl group;
R₄ and R₅ are independently selected from an unsubstituted alkyl group or one of R₄ and R₅ may be the group —(CH₂)ₘ—Y—R₁;
X⁻ is selected from COO⁻, SO₃⁻, OSO₃⁻, PO₃H⁻, PO₃Z⁻, OPO₃H⁻ and OPO₃Z⁻, wherein Z is a monovalent cation;
Y is selected from CONH, NHCO, COO, OCO, NHCONH and O;
l is 0 or 1;
m is an integer from 1 to 10; and
n is an integer from 1 to 5,
provided that
when the printing plate precursor is a heat-sensitive, positive-working lithographic printing plate precursor wherein in the surfactant of formula (I), R₁ is C₁₂H₂₅, l is 0, n is 1, R₂ and R₃ are each H, R₄ and R₅ are each CH₃, and X⁻ is COO⁻, a heat-sensitive layer does not contain a novolac resin which includes a xylenol as a monomer component.

2. A method according to claim 1 wherein the surfactant has the formula (II) 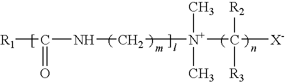
wherein R₁, R₂, R₃, l, m, n and X⁻ are as defined in claim 1.

3. A method according to either of the preceding claims wherein R₁ is an unsubstituted C₈-C₁₈ alkyl group.

4. A method according to any one of the preceding claims wherein each R₂ and each R₃ is independently selected from H or an unsubstituted C₁-C₃ alkyl group.

5. A method according to any one of claims 1, 3 and 4 wherein R₄ and R₅ are independently methyl or ethyl groups.

6. A method according to any one of the preceding claims wherein l is 0, n is an integer from 1 to 3 and m is an integer from 2 to 6.

7. A method according to any one of the preceding claims wherein the surfactant or mixture thereof is present in the composition in a total amount of from about 0.2 to about 5%, based on the total composition weight.

8. A method according to any one of the preceding claims wherein the composition comprises an alkali metasilicate having a molar ratio of SiO₂ to M₂O of ≦1, wherein M is an alkali metal.

9. A method according to any one of the preceding claims wherein the composition comprises a waterglass having a molar ratio of SiO₂ to M₂O of ≧2, wherein M is an alkali metal.

10. A method according to any one of the preceding claims wherein the pH of the composition is from about 12 to about 14.

11. A method according to any one of the preceding claims wherein the triarylmethane dye is a derivative of triphenylmethane or diphenylnaphthylmethane.

12. A method according to any one of the preceding claims wherein the amount of triarylmethane dye(s) is about 0.2 to about 8% based on total solid content of all the layers.

13. A method according to any one of the preceding claims wherein the printing plate precursor is a positive-working printing plate precursor.

14. A method according to any one of the preceding claims wherein the lithographic printing plate precursor is a thermal printing plate precursor.

15. A method according to any one of the preceding claims wherein the lithographic printing plate precursor includes a radiation-sensitive layer comprising an IR-absorbing compound having a maximum absorption wavelength greater than about 750 nm.

16. A method according to any one of the preceding wherein the radiation-sensitive layer contains components which are dispersed in a binder that is soluble in the composition.

17. A method according to claim 16 wherein the binder is a novolac-type phenolic resin or an acetal polymer.

18. The use of an aqueous alkaline developer composition for the reduction or removal of coloration formed during development of an imagewise exposed lithographic printing plate precursor, the coloration being caused by the presence of one or more unsubstituted or substituted triarylmethane dyes associated with one or more layers of the printing plate precursor, at least one of the layers being radiation-sensitive, wherein the composition comprises at least one amphoteric surfactant of formula (I):— 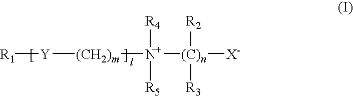
wherein
R₁ is an unsubstituted alkyl group;
each R₂ and each R₃ are independently selected from H, hydroxy and an unsubstituted or substituted alkyl group;
R₄ and R₅ are independently selected from an unsubstituted alkyl group or one of R₄ and R₅ may be the group —(CH₂)ₘ—Y—R₁;
X⁻ is selected from COO⁻, SO₃⁻, OSO₃⁻, PO₃H⁻, PO₃Z⁻, OPO₃H⁻ and OPO₃Z⁻, wherein Z is a monovalent cation;
Y is selected from CONH, NHCO, COO, OCO, NHCONH and O;
l is 0 or 1;
m is an integer from 1 to 10; and
n is an integer from 1 to 5.

19. The use of an aqueous alkaline developer composition as defined in any one of claims 1 to 10 and 18 for the reduction or prevention of sludge formation formed during development of an imagewise exposed lithographic printing plate precursor, the sludge being caused by the presence of one or more unsubstituted or substituted triarylmethane dyes associated with one or more layers of the printing plate precursor, at least one of the layers being radiation-sensitive.
